(19) United States
(12) Patent Application Publication
(10) Pub. No.: US 2017/0175246 A1
(43) Pub. Date: Jun. 22, 2017

(54) METHOD FOR PRODUCTION OF A COMPOSITE LAYER COMPRISING A PLASTIC FOIL AND A LAYER DEPOSITED THEREON

(71) Applicant: Fraunhofer-Gesellschaft zur Förderung der angewandten Forschung e.V., Munich (DE)

(72) Inventors: Hendrik Drese, Greiz (DE); John Fahlteich, Dresden (DE); Wolfgang Schwarz, Dresden (DE); Frank-Holm Rögner, Dresden (DE); Nicolas Schiller, Stolpen OT Helmsdorf (DE)

(21) Appl. No.: 15/357,476

(22) Filed: Nov. 21, 2016

(30) Foreign Application Priority Data
Dec. 16, 2015 (DE) 10 2015 122 024.5

(51) Int. Cl. C23C 14/00; H01L 21/02; C23C 14/20; C23C 14/32; C23C 14/35

(52) U.S. Cl. CPC C23C 14/0036; C23C 14/325; C23C 14/35; C23C 14/205; H01L 21/02422; H01L 21/02532; H01L 21/02631; C23C 16/50

(57) ABSTRACT

Methods are provided for production of a composite layer comprising a plastic foil and a layer deposited directly thereon. A method for production of a composite layer comprising a plastic foil and at least one layer deposited directly onto the plastic foil by means of chemical gas-phase deposition within a vacuum chamber may be provided, wherein the plastic foil has a proportion of at least 20 percent by mass of a metal element or of a semiconductor element, wherein during the layer deposition, at least one monomer is supplied into the vacuum chamber and a plasma is formed within the vacuum chamber. After completed deposition of the layer, at least one surface region of the layer is exposed to accelerated electrons.

### CROSS-REFERENCE TO RELATED APPLICATIONS

This application claims priority under 35 USC §119 to German Patent Application DE 10 2015 122 024.5, filed Dec. 16, 2015, the entire contents of which are hereby incorporated herein by reference.

### TECHNICAL FIELD

The invention relates to a method for depositing a layer onto a plastic foil by means of a plasma-based, chemical gas-phase deposition in a vacuum.

### BACKGROUND

The application of functional layers onto the surface of plastic foils is known, or also the deposition of such layers, in order to change, for example, the optical properties or the barrier properties of the plastic foil with respect to water vapor and/or oxygen. For the application of such layers onto the surface of large-area plastic foils, methods of chemical gas-phase deposition (also called chemical vapor deposition or CVD), in particular, have proven useful because with these methods, fast deposition rates can be attained and a wide variety of layer materials can be deposited. It has proven advantageous to carry out the methods of chemical gas-phase deposition under the influence of a plasma in order to atomize and to stimulate the starting materials to enter into a chemical reaction. These types of methods are also known as Plasma Enhanced Chemical Vapor Deposition (PECVD).

Document DE 10 2008 028 542 A1 discloses a PECVD method in which a magnetron is used to generate a plasma. In this method, the magnetron is used primarily to generate the plasma. However, removal of particles from the magnetron target and entry of these particles into a layer deposited on a substrate are not desirable.

Additional PECVD methods are known from DE 10 2008 050 196 A1. In the dynamic coating of a plastic foil, here too a magnetron is used to create plasma, wherein a monomer inlet is arranged either in front of or behind the magnetron, in the direction of motion of the plastic foil, in order to form a layer with a gradient deposited onto the plastic foil. Meanwhile, optionally, a contribution can be made to the deposition of the layer with particles sputtered on the magnetron target.

Also in DE 10 2010 055 659 A1, magnetron PECVD methods are described which are used in the deposition of dielectric layers onto plastic substrates. In this method, during the magnetron sputtering, a silicon-containing precursor and a reactive gas are introduced into the vacuum chamber. Both reaction products of sputtered magnetron target particles and reaction products of the precursor are involved with the reactive gas in constructing the layer.

All known methods have in common that the composite layers created in this manner, comprising a plastic substrate and a layer or layers deposited thereon, display only a limited mechanical stability, especially with regard to bending behavior or elasticity, which often cannot withstand an applied stress. Thus the handling of such products can result in crack formation in the layered system, and consequently result in adverse effects on their functional reliability. It is known that the flexibility of such layered composites can be increased by adding organic components to the deposited layer, these components result in an organic crosslinking or partial organic crosslinking of the deposited layer. Nonetheless, the attainable flexibility and elasticity of the composite layers is often not sufficiently stable or is often not stable in the long-term.

### BRIEF DESCRIPTION OF THE DRAWINGS

FIG. 1 illustrates a schematic depiction of an apparatus, which can be used to implement the inventive method.

### DETAILED DESCRIPTION

The invention relates to a method for depositing an organic-modified silicon-containing layer onto a plastic foil by means of a plasma-based, chemical gas-phase deposition in a vacuum, wherein the produced composite layer displays an improved elasticity in comparison to the prior art.

Therefore the invention is based on the technical problem of providing a method for producing a layered composite such that one or more of the disadvantages of the prior art can be overcome. In particular, with the invention, a method is described for production of a composite layer comprising a plastic foil and at least one layer deposited directly onto the plastic foil, wherein the composite layer displays a greater elasticity under tensile and/or flexure load in comparison to the prior art.

The solution to the technical problem is achieved by means of the objects with the features of patent claim 1. Additional advantageous embodiments of the invention are presented in the dependent claims.

In the inventive method for production of a composite layer, at least one layer is deposited directly onto the plastic foil by means of chemical gas-phase deposition within a vacuum chamber. Consequently, no additional layer is located between the plastic foil and the deposited layer. In this process, the deposited layer has an at least 20 percent mass fraction of a metal element or of a semiconductor element. In particular, titanium and aluminum are suitable as the metal element, and silicon is suitable as the semiconductor element. During deposition of the layer, at least one monomer is introduced into the vacuum chamber, and a plasma is formed within the vacuum chamber. The plasma can be generated, for example, by means of a sputter magnetron or by means of a hollow cathode arc discharge. Optionally, during deposition of the layer, at least one reactive gas, such as nitrogen or oxygen, for example, can be introduced into the vacuum chamber.

As one essential feature of the invention, after deposition of the layer is completed, at least one surface region of the layer is exposed to accelerated electrons. Surprisingly, it has been seen that a composite layer composed of a plastic foil and a layer deposited thereon, which contains a non-negligible fraction of a metal element or of a semiconductor element of at least 20 percent by mass, undergoes an improvement in its elasticity and flexibility due to the exposure to accelerated electrons.

In one embodiment of the invention, the composite layer of plastic foil and deposited layer is passed over a cooling element, such as a cooling roller, for example, during the exposure to the accelerated electrons. This has the advantage (over a system without the cooling element) that a greater energy dosage can be applied into the composite layer over an equal exposure time, without damaging the composite layer. Alternatively, the exposure of the deposited layer to accelerated electrons can also take place in a region where the plastic foil is not in contact with a cooling element.

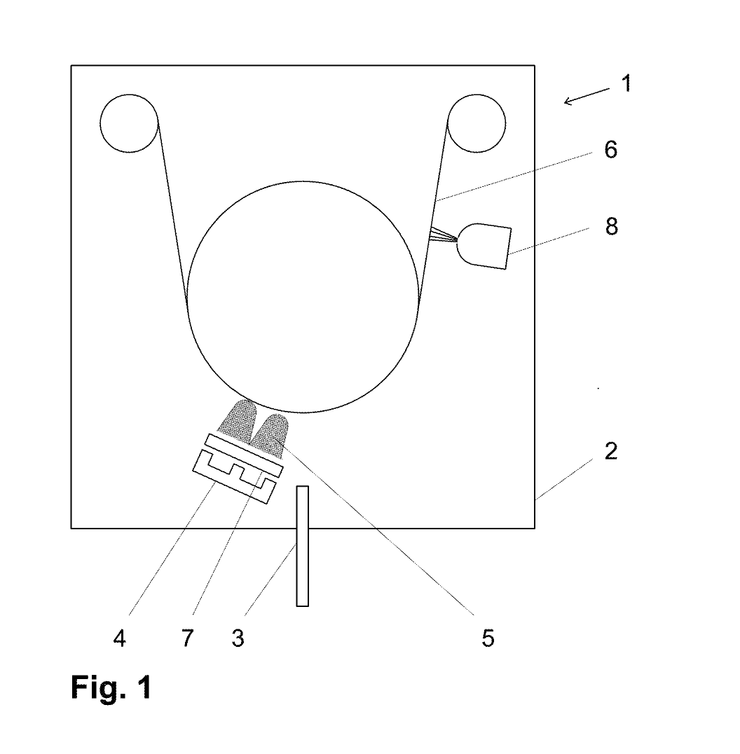

The present invention will be explained in greater detail below based on an exemplary embodiment. FIG. 1 provides a schematic depiction of an apparatus 1, which can be used to implement the invented method. The monomer HMDSO, the reactive gas oxygen and the operating gas argon are introduced into a vacuum chamber 2 through an inlet 3. By means of a sputter magnetron 4, a magnetron plasma 5 is created within the vacuum chamber 2, which atomizes the monomer HMDSO and also activates the atomized monomer constituents and stimulates the chemical layer deposition. The atomized monomer constituents thus react with the reactive gas so that an organic-modified silicon oxide layer with a layer thickness of 200 nm is deposited on a plastic foil 6 passing through the vacuum chamber 2. The organic modified silicon oxide layer thus contains the elements silicon and oxygen, and additionally also the elements carbon and hydrogen.

The sputter magnetron, which is equipped with a titanium target, is operated such that essentially no sputter abrasion of the target 7 occurs. Consequently, the magnetron is used solely to generate the plasma. But alternatively, a magnetron can also be operated such that a sputter abrasion of the magnetron occurs and the sputter particles are involved in formation of the layer.

A portion of the composite layer produced in this manner from plastic foil 6 and the deposited organic-modified silicon oxide layer was separated from the foil roll and subjected to a stretch test. Under a light microscope with a stretching of the composite layer of 1.7%, the initial cracks were detected in the deposited layer.

The portion of the composite layer foil roll not subjected to the stretch test was subsequently passed through a vacuum chamber in which the deposited layer was exposed to accelerated electrons. For this purpose, an electron generator 8 known from the prior art was used to generate an area beam. For example, band-emitters can be used for this purpose. But alternatively, other electron generators can also be used, such as an axial emitter whose focused electron beam is controlled according to a specified pattern, such as a linear pattern, across the surface of the deposited layer, so that the surface area of the deposited layer is scanned with the electron beam. The depth of penetration of an electron beam into an object is known to be adjustable. In the invented method, the depth of penetration of the applied electron beam can be adjusted preferably such that the maximum energy applied by the electron beam develops within the deposited layer.

Tests with various plastic foils and layer materials of different compositions deposited thereon have shown that the exposure of the deposited layer to accelerated electrons is to be implemented with a minimum energy dosage of 100 kJ/m² in order to obtain the advantage of improved elasticity properties of the composite layer of plastic foil and layer deposited thereon. The maximum energy applied by the accelerated electrons into the composite layer, without thereby causing any damage to the composite layer, depends on the particular plastic foil used, on the material composition of the deposited layer and on its layer thickness, but this factor can be easily determined by laboratory tests.

After exposure of the deposited layer to the accelerated electrons, a portion of the composite layer treated in this manner was subjected to a stretch test. Under a light microscope, the initial cracks in the deposited layer were found starting at a stretch of more than four percent. The method according to the invention is thus suitable for producing a composite layer consisting of a plastic foil and a layer deposited thereon, wherein the composite layer displays an improved stretchability until onset of crack formation compared to the prior art.

The method according to the invention is particularly suitable for the production of a composite layer in which silicon is used as the semiconductor element within the layer deposited onto a plastic foil. The deposited layer can additionally feature at least one of the elements from the group of carbon, oxygen, and hydrogen. Layers of this kind are used, for example, as layers with a barrier effect against water vapor and/or oxygen, as anti-scratch coatings and as optical layers with a low refractive index. If the oxygen in the layer composition listed above is replaced by the element nitrogen, then the layer deposited on the plastic foil can also perform the function of an optically active layer with a high refractive index. Alternatively, an optically active layer with a high refractive index can also be produced with the invented method, if titanium is deposited as the metal element within the layer on a plastic foil.

For deposition of a layer with the aforementioned layer compositions by means of chemical gas-phase deposition, at least one of the components HMDSO, HMDSN, TMS, TEOS, TEMAT, TDMAT, TMA, titanium propoxide, titanium isopropoxide, for example, can be introduced into the vacuum chamber.

To clarify the use of and to hereby provide notice to the public, the phrases “at least one of <A>, <B>, . . . and <N>” or “at least one of <A>, <B>, <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

We claim:

1. A method for production of a composite layer comprising a plastic foil and at least one layer deposited directly onto the plastic foil by means of gas-phase deposition within a vacuum chamber, wherein the plastic foil has a proportion of at least 20 percent by mass of a metal element or a semiconductor element, wherein during the layer deposition, at least one monomer is supplied into the vacuum chamber and a plasma is formed within the vacuum chamber, wherein after completed deposition of the layer, at least one surface region of the layer is exposed to accelerated electrons.

2. The method of claim 1, wherein a magnetron-plasma is formed in the vacuum chamber.

3. The method of claim 1, wherein a hollow cathode-plasma is formed in the vacuum chamber.

4. The method of claim 1, wherein reactive gas containing oxygen and/or nitrogen is additionally supplied into the vacuum chamber.

5. The method of claim 1, wherein the deposited layer is exposed to accelerated electrons while the composite layer is passed over a cooling roller.

6. The method of claim 1, wherein titanium and/or aluminum is deposited as the metal element onto the plastic foil.

7. The method of claim 1, wherein silicon is deposited as the semiconductor element onto the plastic foil.

8. The method of claim 7, wherein in addition to silicon, at least one of the elements from the group of carbon, hydrogen, oxygen, or nitrogen is deposited onto the plastic foil.

9. The method of claim 1, wherein the exposure of the deposited layer to accelerated electrons is conducted at an energy dosage of at least 100 kJ/m².

10. The method of claim 1, wherein for the deposition of the layer by means of chemical gas-phase deposition, at least one of HMDSO, HMDSN, TMS, TEOS, TEMAT, TDMAT, TMA, titanium propoxide, or titanium isopropoxide is supplied into the vacuum chamber.
